(19) United States
(12) Patent Application Publication
(10) Pub. No.: US 2026/0334109 A1
(43) Pub. Date: Oct. 22, 2026

(54) METHOD OF FORMING A STRUCTURE INCLUDING A SILICON NITRIDE LAYER

(71) Applicant: ASM IP Holding B.V., Almere (NL)

(72) Inventors: Hirotsugu Sugiura, Tokyo (JP); Daiki Nojiri, Tokyo (JP)

(21) Appl. No.: 19/650,591

(22) Filed: Apr. 17, 2026

Related U.S. Application Data
(60) Provisional application No. 63/792,554, filed on Apr. 22, 2025.

(51) Int. Cl. H10P 14/60; C23C 16/458; C23C 16/52; H10P 14/694; H10P 72/76

(52) U.S. Cl. CPC H10P 14/6336; C23C 16/4586; C23C 16/52; H10P 14/6532; H10P 14/6682; H10P 14/69433; H10P 72/7616

(57) ABSTRACT

A method of forming a structure comprising a silicon nitride layer is disclosed. An exemplary method includes using high frequency power and low frequency power during deposition and/or treatment of the silicon nitride layer to form films with desired properties. In some cases, the high and/or low frequency power is pulsed on and off to provide additional ability to tune desired properties.

### CROSS-REFERENCE TO RELATED APPLICATIONS

This application claims priority to U.S. Provisional Patent Application Ser. No. 63/792,554 filed Apr. 22, 2026 titled METHOD OF FORMING A STRUCTURE INCLUDING A SILICON NITRIDE LAYER, the disclosure of which is hereby incorporated by reference in its entirety.

### FIELD OF INVENTION

The present disclosure generally relates to methods of forming thin films and to structures including the thin films. More particularly, the disclosure relates to methods of forming structures that include a silicon nitride layer, to structures including such layers, and to systems for forming the layers.

### BACKGROUND OF THE DISCLOSURE

Silicon nitride (SiN) material can be used for a wide variety of applications. For example, during the formation of electronic devices, silicon nitride can be used to form insulating layers, etch stop layers, spacers, or the like.

For many applications, it may be desirable to deposit SiN on a surface of a substrate at relatively low (e.g., less than 650 °C) temperatures. Plasma-enhanced chemical vapor deposition (PECVD) can be used to deposit SiN layers on a substrate surface at relatively low temperatures.

Typical PECVD techniques to deposit SiN layers include use of a silicon precursor and a reactant. The reactant is typically used to form a plasma. Activated species formed from the plasma can react with the silicon precursor or derivatives thereof to form the SiN. Although such techniques may work well for some applications, properties of the SiN layers using activated species formed using typical plasma formation techniques may not allow for a desired etch selectivity and/or other properties, such as surface roughness, density, stress, and/or composition. Additionally or alternatively, such techniques may be relatively time consuming. Accordingly, improved methods are desired for forming structures that include SiN.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to methods of forming a structure comprising a silicon nitride layer. While the ways in which various embodiments of the present disclosure address drawbacks of prior methods and structures are discussed in more detail below, in general, various embodiments of the disclosure provide improved methods to form SiN layers with desired properties, such as desired etch resistance, desired composition, desired stress, desired density, desired roughness (or smoothness), and/or the like. Additionally or alternatively, exemplary methods provide a relatively efficient process to form a structure that includes a SiN layer.

In accordance with embodiments of the disclosure, a method of forming a structure comprising a silicon nitride layer includes providing a substrate within a reaction chamber of a reactor, providing a silicon precursor within the reaction chamber, providing a first nitrogen-containing reactant within the reaction chamber, and forming a plasma within the reaction chamber while providing one or more of the silicon precursor and the nitrogen-containing reactant. In accordance with various examples of these embodiments, forming the plasma includes providing a first plasma power to an electrode within the reaction chamber while providing one or more of the silicon precursor and the first nitrogen-containing reactant and providing a second plasma power to the electrode within the reaction chamber while providing one or more of the silicon precursor and the first nitrogen-containing reactant, wherein a frequency of the first plasma power is greater than a frequency of the second plasma power. In accordance with examples of the disclosure, a frequency of the first plasma power is greater than 1 MHz, greater than 10 MHz, or is between about 50 MHz and about 200 MHz. The frequency of the second plasma power is less than 5 MHz, less than 1 MHz, or is between about 100 kHz and about 2 MHz. In accordance with further examples, the second plasma power is pulsed at a pulsed frequency. The second plasma power pulsed frequency can be between, for example, about 50 Hz and about 5 kHz. A duty ratio of the second plasma power can be between about 1% and about 50% or between about 1% and about 20%. Providing and pulsing the second plasma power allows for formation of silicon nitride layers with desired properties (e.g., a density of greater than 2.8 g/cm³ and relatively low hydrogen content and/or relatively low surface roughness—e.g., less than 0.5 nm RMS as measured by atomic force microscopy). Additionally or alternatively, the first plasma power can be pulsed. A pulse frequency of the first plasma power can be between about 50 Hz and about 100 Hz. A duty ratio of the first plasma power can be between about 1% and about 90% or between about 1% and about 20%. A power of the first plasma power can be at least 2 times or at least 10 times greater than a power of the second plasma power. In accordance with further examples of these embodiments, the silicon precursor comprises a silane. In accordance with yet further examples, the first nitrogen-containing reactant comprises one or more of nitrogen (N₂), ammonia (NH₃), hydrazine (N₂H₄), or triazane (N₃H₅). Exemplary methods can further include a step of providing a second nitrogen-containing reactant. The second nitrogen-containing reactant can be or include one or more of ammonia (NH₃), hydrazine (N₂H₄), or triazane (N₃H₅). In some cases, and in accordance with further examples, a ratio of a flowrate of the first nitrogen-containing reactant to a flowrate of the silicon precursor is greater than 25, greater than 50, or is between about 1500 and about 2000. In some cases, a ratio of atomic N to atomic silicon provided by the reactant(s) and precursor(s) is greater than 25, greater than 50, or is between about 2000 and about 40000. The method can further include a step of providing a hydrogen-containing reactant to the reaction chamber. A ratio of a flowrate of the hydrogen reactant to a flowrate of the silicon precursor can be greater than 5 or be between about 80 and about 800.

In some cases, the method can include treating deposited material. In some cases, the step of treating the deposited material includes forming a plasma. In accordance with examples of such cases, the step of treating includes providing a treatment gas for a period and applying a pulsed treatment plasma power for a period.

In accordance with further exemplary embodiments of the disclosure, a structure includes a layer comprising SiN. The structures can be formed using, for example, a method as described herein.

In accordance with additional embodiments, a reactor system is provided. Exemplary reactor systems include a reaction chamber, a precursor source coupled to the reaction chamber, a treatment gas source coupled to the reaction chamber, one or more reactant sources coupled to the reaction chamber, and a controller. The controller can be configured to perform a method as described herein. The reactor system can include a plurality of reaction chambers. One or more steps that are performed by the controller can be performed in one or more of the plurality of reaction chambers.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method of forming a structure comprising a silicon nitride layer in accordance with at least one embodiment of the disclosure.

FIG. 2 illustrates density and stress data for silicon nitride films formed in accordance with at least one embodiment of the disclosure.

FIG. 3 illustrates density and hydrogen content data for silicon nitride films formed in accordance with at least one embodiment of the disclosure.

FIG. 4 illustrates additional density and hydrogen content data for silicon nitride films formed in accordance with at least one embodiment of the disclosure.

FIG. 5 illustrates a schematic diagram of a reactor system in accordance with examples of the disclosure.

FIG. 6 illustrates a schematic diagram of a reactor system, having multiple modules, in accordance with examples of the disclosure.

FIGS. 7-9 illustrate timing sequences suitable for use with a method in accordance with examples of the disclosure.

FIG. 10 illustrates surface roughness versus deposition rate for SiN films in accordance with examples of the disclosure.

FIG. 11 illustrates effects of cyclic deposition and continuous wave (CW) plasma treatment on roughness of silicon nitride films in accordance with additional examples.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particularly disclosed embodiments described below.

The present disclosure generally relates to methods of forming a structure comprising a silicon nitride (SiN) layer. As set forth in more detail below, methods described herein can be used to form silicon nitride layers with desired properties, such as relatively high density, relatively high wet etch resistance, relatively low surface roughness, and/or with desired compositions, such as desired (e.g., low hydrogen) concentrations.

Exemplary methods described herein can be used to form structures that can be used in a variety of applications, such as the formation of electronic devices. For example, the methods can be used to form structures suitable for etch stop layers, spacer formation, or the like.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate.

In some embodiments, film refers to a layer extending in a direction perpendicular to a thickness direction. In some embodiments, layer refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers.

In this disclosure, continuously or continuous or continually can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

As used herein, a silicon nitride layer or a layer comprising SiN includes material with silicon and nitrogen. In some embodiments, SiN layers may comprise one or more elements in addition to Si and N, such as H. In some embodiments, the SiN layer comprises less than 8, 7, or 6 at % hydrogen or other impurities.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like in some embodiments. Further, in this disclosure, the terms comprising, including, constituted by and having can refer independently to typically or broadly comprising, comprising, consisting essentially of, or consisting of in some embodiments. In this disclosure, any defined meanings do not necessarily exclude ordinary and customary meanings in some embodiments.

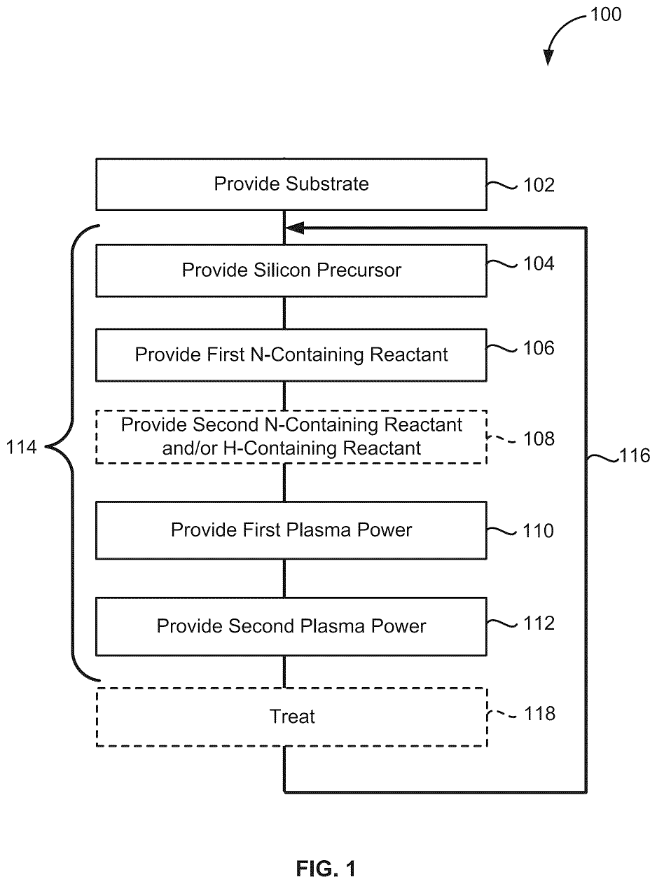

Turning now to the figures, FIG. 1 illustrates a method 100 of forming a structure comprising a silicon nitride layer in accordance with examples of the disclosure. Method 100 includes providing a substrate within a reaction chamber (step 102), providing a silicon precursor within the reaction chamber (step 104), providing a first nitrogen-containing reactant within the reaction chamber (step 106), optionally providing a second nitrogen-containing and/or a hydrogen-containing reactant within the reaction chamber (step 108), providing a first plasma power (step 110), providing a second plasma power (step 112), and optionally treating deposited material (step 118). Although separately illustrated, one or more (e.g., all) of steps 104-112 can overlap in time. For example, steps 104-112 can overlap in time to perform a plasma-enhanced chemical vapor deposition (PECVD) process, illustrated as 114. In some cases, one or more steps 104-118 can be repeated, as illustrated by loop 116.

The substrate provided during step 102 can be provided within any suitable reaction chamber of any suitable reactor. In accordance with examples of the disclosure, the reaction chamber can form part of a chemical vapor deposition (CVD) reactor, such as a PECVD reactor. The reactor can be a single substrate reactor or a batch reactor. A reactor including the reaction chamber can be provided with a heater to activate the reactions by elevating the temperature of one or more of the substrate and/or the reactants and/or precursors. By way of particular examples, the reaction chamber can be or include a capacitively-coupled plasma reactor. An exemplary reactor and reactor system suitable for use with method 100 is described in more detail below.

After step 102 and during or before steps 104-108, the substrate can be brought to a desired temperature and pressure for forming the silicon nitride layer. By way of examples, a temperature (e.g., of a substrate or a substrate support) within a reaction chamber can be between about 100 °C and about 600 °C or between about 400 °C and about 500 °C. A pressure within the reaction chamber during one or more of steps 104-108 can be between about 100 Pa and about 3000 Pa or between about 300 Pa and about 1000 Pa or between about 300 Pa and about 500 Pa.

During step 104, the silicon precursor is provided within the reaction chamber. The silicon precursor can be or include, for example, a silane. Exemplary silanes can be represented by the following formula, where n ranges from 1 to 4.

SiₙH₂ₙ₊₂

In some cases, the silicon precursor is provided to the reaction chamber using a carrier gas. Exemplary suitable carrier gases include one or more of nitrogen, argon, helium, or any mixture thereof. A flowrate of the carrier gas used to provide the silicon precursor to the reaction chamber can be between about 100 and about 5000 sccm or between about 2000 and about 4000 sccm. In some cases, the silicon precursor is provided to the reaction chamber without aid of a carrier gas. In either case, a flowrate of the silicon precursor (exclusive of the carrier gas) can be between about 5 sccm and about 20 sccm or between about 10 sccm and about 50 sccm.

During step 106, the first nitrogen-containing reactant is provided within the reaction chamber. As noted above, step 106 can overlap with step 104.

In accordance with various examples, the first nitrogen-containing reactant does not include oxygen. In accordance with particular examples, the first nitrogen-containing reactant includes nitrogen and hydrogen. Exemplary first nitrogen-containing reactants suitable for step 106 include one or more of nitrogen (N₂), ammonia (NH₃), hydrazine (N₂H₄), or triazane (N₃H₅). In accordance with more particular examples, the nitrogen-containing reactant comprises or consists essentially of one or more of N₂, NH₃, NH₄, N₂H₂, N₂H₄, or a mixture thereof. In accordance with examples of the disclosure, a flowrate of the first nitrogen-containing reactant to the reaction chamber is higher than a flowrate of the silicon precursor to the reaction chamber. For example, a ratio of a flowrate of the first nitrogen-containing reactant to a flowrate of the silicon precursor can be greater than 25, greater than 50, or be between about 1500 and about 2000. In some cases, a ratio of atomic nitrogen of the first nitrogen-containing reactant and/or of all nitrogen-containing reactants in nitrogen-containing reactant(s) flowrate to atomic silicon in the silicon precursor flowrate can be greater than 25, greater than 50, or be between about 1500 and about 2000. A flowrate of the first nitrogen-containing reactant can be between about 1 and 20 SLM or between about 2 and 10 SLM or between about 6 and 10 SLM.

During step 108, a second nitrogen-containing reactant and/or a hydrogen-containing reactant is provided to the reaction chamber. If both the second nitrogen-containing reactant and the hydrogen-containing reactant are provided, such reactants can be provided together or separately. In some cases, the second nitrogen-containing reactant may include hydrogen and/or the hydrogen-containing reactant may include nitrogen.

In some cases, the first nitrogen-containing reactant comprises N₂, and the second nitrogen-containing reactant is or includes one or more of ammonia (NH₃), hydrazine (N₂H₄), or triazane (N₃H₅).

The hydrogen-containing reactant can be or include H₂. A flowrate of the hydrogen-containing reactant can be greater than the flowrate of the silicon precursor. For example, a ratio of a flowrate of the hydrogen-containing reactant to a flowrate of the silicon precursor can be greater than 5 or be between about 80 and about 800. In some cases, a flowrate of the hydrogen-containing reactant to the reaction chamber is greater than 100 sccm, greater than 250 sccm, greater than 500 sccm, and/or less than 5 SLM, 4 SLM, or 3 SLM.

By way of particular examples, method 100 can include providing the silicon precursor, providing the first nitrogen-containing reactant (e.g., N₂), and providing the hydrogen-containing reactant to the reaction chamber. In another example, method 100 can include providing the silicon precursor, providing the first nitrogen-containing reactant (e.g., N₂), and providing the second nitrogen-containing reactant (e.g., NH₃) to the reaction chamber. In yet another example, method 100 can include providing the first nitrogen-containing reactant (e.g., N₂), providing the second nitrogen-containing reactant (e.g., NH₃, N₂H₄, and/or N₃H₅), and providing the hydrogen-containing reactant (e.g., H₂) to the reaction chamber.

During step 110, a first plasma power is provided to an electrode within the reaction chamber while providing one or more of the silicon precursor and the first nitrogen-containing reactant. As illustrated below, in accordance with examples of the disclosure, the electrode is within or forms at least part of a susceptor within the reaction chamber. The susceptor can include a body comprising one or more of aluminum nitride or aluminum. In addition to the electrode, one or more heating elements may be on or embedded in the susceptor body.

A power of the first plasma power can be between about 10 W and about 2000 W or between about 50 W and about 500 W—e.g., for a 300 mm diameter substrate. A frequency of the first plasma power can be between about 50 MHz and about 200 MHz or between about 50 MHz and 100 MHz. A duration of step 110 can be between about 5 seconds and about 3600 seconds. The power can be continuously provided during step 110. Alternatively, the power of the first plasma power can be pulsed on and off or high to low. A duty ratio of the pulsed first plasma power can be between about 1 and about 90% or between about 1% and about 20%. When pulsed, the first plasma power can have a pulse frequency of about 50 Hz to about 100 Hz. The first plasma power can be provided as a pulsed wave. The first plasma power can be provided to the electrode via a conductive rod from a lower region of the reactor.

During step 112, a second plasma power is provided to the electrode (e.g., via the conductive rod) within the reaction chamber while providing one or more of the silicon precursor and the first nitrogen-containing reactant. In accordance with examples disclosed herein, a frequency of the first plasma power is greater than a frequency of the second plasma power. In accordance with further examples, a power of the first plasma power is greater than a power of the second plasma power. By way of examples, a power of the first plasma power is at least 2 times, 5 times or at least 10 times greater than a power of the second plasma power. A power of the second plasma power can be, for example, between greater than 0 W and 1000 W or between about 10 W and about 100 W. A (e.g., wave) frequency of the second plasma power can be between about 100 kHz and about 2 MHz or between about 400 kHz and about 500 kHz.

The second plasma power can be a continuous wave or can be pulsed on and off (or high and low) at a pulsed frequency during step 112. The pulsed frequency can be between about 50 Hz and about 5 kHz or between about 50 Hz and about 500 Hz. A duty ratio can be between about 1 and about 50% or between about 1 and about 20%. The duty ratio can be defined as a percent of plasma power on-time/(on-time+off-time); on and off can be replaced with high and low in the preceding equation. The second plasma power can be provided as a pulsed wave.

In accordance with examples of the disclosure, pulses of the first plasma power and the second plasma power can be synchronized. In accordance with other examples, pulses of the first plasma power and the second plasma power are not synchronized or are out of phase—e.g., by about 180 degrees.

During steps 110 and/or 112, a plasma is formed within the reaction chamber while providing one or more of the silicon precursor and the first nitrogen-containing reactant by providing a plasma power to an electrode within the reaction chamber. Using high frequency/first plasma power and low frequency/second plasma power (e.g., pulsed low frequency power) allows for formation of SiN films with desired properties (e.g., stress and composition) in a time efficient manner. Further, using pulsed plasma during deposition can provide for deposited material with relatively low surface roughness.

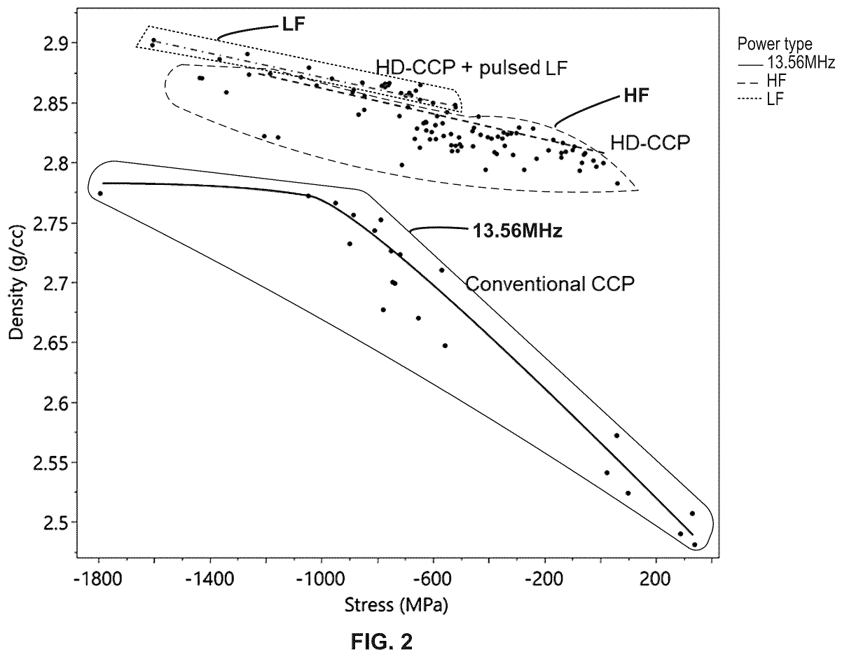

FIG. 2 illustrates film stress vs density plot of PECVD SiN by conventional CCP and according to method 100 (HD-CCP). The conventional CCP case uses the 13.56 MHz of RF frequency. 13.56 MHz plasma exhibits a high ion energy tale due to a plasma sheath oscillation; ions can follow this oscillation. This ion bombardment makes film stress high at high film density. On the other hand, HD-CCP can be deposited high-density SiN film with relatively lower stress. The sheath oscillation of 60 MHz of RF (HF, first plasma power) frequency is too high for ions to follow it. Moreover, high-density plasma can dissociate the precursor gases efficiently and enhance the crosslinking reaction at the growth surface. As a result, HD-CCP can deposit high-density SiN film with lower compressive stress.

Ions can be used to increase film density at the lower deposition temperature. To utilize the benefit of ion bombardment, pulsed low frequency (LF, second plasma power) is applied to HD-CCP. The benefit of pulsed LF power is independent control of ion bombardment energy and flux separately. Duty ratio of second plasma power pulses can control ion flux, while input power can control ion bombardment energy. This independent ion bombardment control enables one to increase film density while maintaining stress levels the same as shown in FIG. 2 (HD-CCP+pulsed LF power). High ion bombardment energy helps the crosslinking reaction at the growth surface, and relaxation time by LF power off duration helps stress reduction.

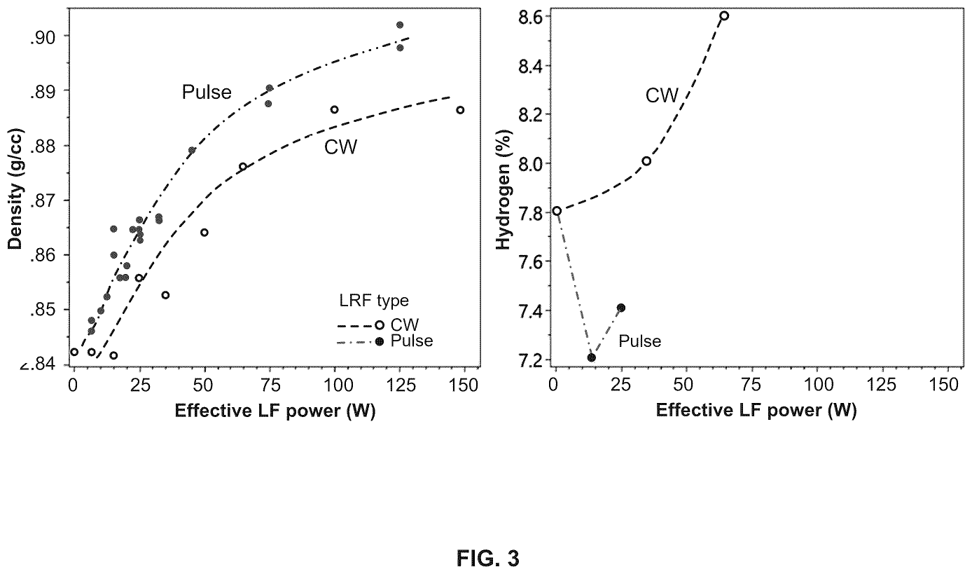

FIG. 3 shows the film density and hydrogen content vs effective LF power (W) of continuous wave (CW) and pulsed wave second plasma power. As noted above, SiN deposited using pulsed LF power showed higher film density than the same effective power of CW LF power. Furthermore, pulsed LF power has a huge benefit on hydrogen content in the film. Hydrogen content can be measured by hydrogen forward scattering spectrometry (HFS). Hydrogen content increased with increasing effective LF power in case of CW power, while it decreased by applying pulsed LF power. When effective LF power of pulsed LF was increased, hydrogen content increased the same as CW LF power. The precise control of ion bombardment enables high density SiN film with moderate stress and low hydrogen content.

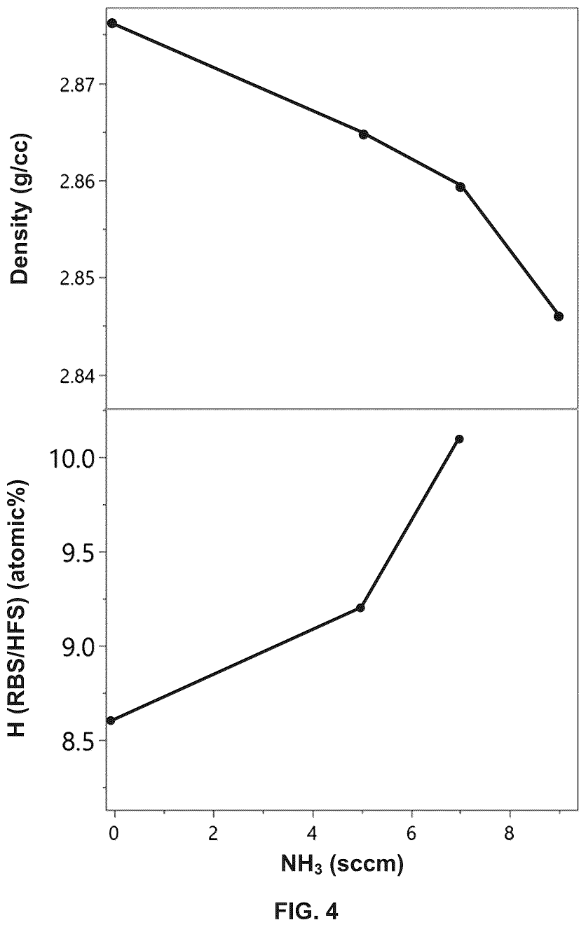

FIG. 4 illustrates dependence of NH₃ (as a second nitrogen-containing reactant) flow rate on film density and hydrogen content. The gas mixture was SiH₄ 40 sccm, N₂ (first nitrogen-containing reactant) 8500 sccm, H₂ 2500 sccm and NH₃. The film density increased and hydrogen concentration decreased with decreasing NH₃ flow rate. When N₂ and H₂ flowrates are high enough, nitrogen radicals and hydrogen radicals are generated from N₂ and H₂. NH₃ is not needed to generate nitrogen radicals to enhance the SiN bond generation. NH₃ can easily generate NH termination in the film and increase the hydrogen content of the SiN film.

Table 1 shows a film property comparison between several CCP processes. The SiN film which was deposited by HD-CCP, pulsed LRF and no NH₃ showed the density 2.86 g/cc, H content 7.2%. Further results with hydrogen concentration of 6 at % or less were also achieved.

TABLE 1

| | HD-CCP + | | | | |
|---|---|---|---|---|---|
| | pulsed | | | | Conventional |
| | LRF | HD-CCP | HD-CCP | HD-CCP | CCP |
| NH₃ | Without | Without | Without | With | With |
| LRF | Pulse | CW | None | CW | CW |
| Density | 2.86 | 2.85 | 2.84 | 2.84 | 2.77 |
| (g/cm³) | | | | | |
| H content | 7.2 | 8.0 | 7.8 | 9.9 | NA |
| by HFS (%) | | | | | |
| Stress | −661 | −860 | −437 | −610 | −1046 |
| (MPa) | | | | | |

Returning to FIG. 1, as noted above, method 100 can include a treatment step 118. Treatment step 118 can be performed after a predetermined deposition time of chemical vapor deposition (PECVD) process 114 or steps 104-112. For example, a deposition time of process 114 can be selected, such that greater than 0 and less than 10 nm of SiN is deposited prior to treatment step 118.

During step 118, a treatment gas and a treatment plasma power can be provided to a reaction chamber (e.g., the same reaction chamber used for process 114). The treatment gas can include, for example, N₂, NH₃, N₂H₄, N₃H₅, Ar, He, or Xe.

The treatment plasma power can include a first treatment plasma power and a second treatment plasma power. The first treatment plasma power can be between about 10 W and about 2000 W or between about 50 W and about 500 W—e.g., for a 300 mm diameter substrate. A frequency of the first treatment plasma power can be between about 50 MHz and about 200 MHz or between about 50 MHz and 100 MHz. The first treatment plasma power can be provided as a pulsed wave. The first treatment plasma power can be pulsed on and off or high to low. A duty ratio of the first treatment plasma power can be between about 1% and about 90% or between about 1% and 20%. The first treatment plasma power can have a pulse frequency of about 50 Hz to about 100 Hz. The first treatment plasma power can be provided to the electrode via a conductive rod from a lower region of the reactor.

The second treatment plasma power can be provided as a pulsed wave. The second treatment plasma power can be pulsed on and off (or high between and low) at a pulsed frequency during step 118. The pulsed frequency of the second treatment plasma power can be between about 50 Hz and about 5 kHz or between about 50 Hz and about 500 Hz. A duty ratio of the second treatment plasma power can be between about 1 and about 50% or between about 1 and about 20%.

In accordance with examples of the disclosure, pulses of the first treatment plasma power and the second treatment plasma power can be synchronized. In accordance with other examples, pulses of the first treatment plasma power and the second treatment plasma power are not synchronized or are out of phase—e.g., by about 180 degrees.

A duration of step 118 can be between about 5 seconds and about 3600 seconds. The duration of step 118 can be adjusted to have a desired effect on surface roughness and stress.

As illustrated in FIG. 1, steps 104-112 and 118 can be repeated (loop 116) —e.g., until a desired thickness is obtained or a desired number of cycles are performed.

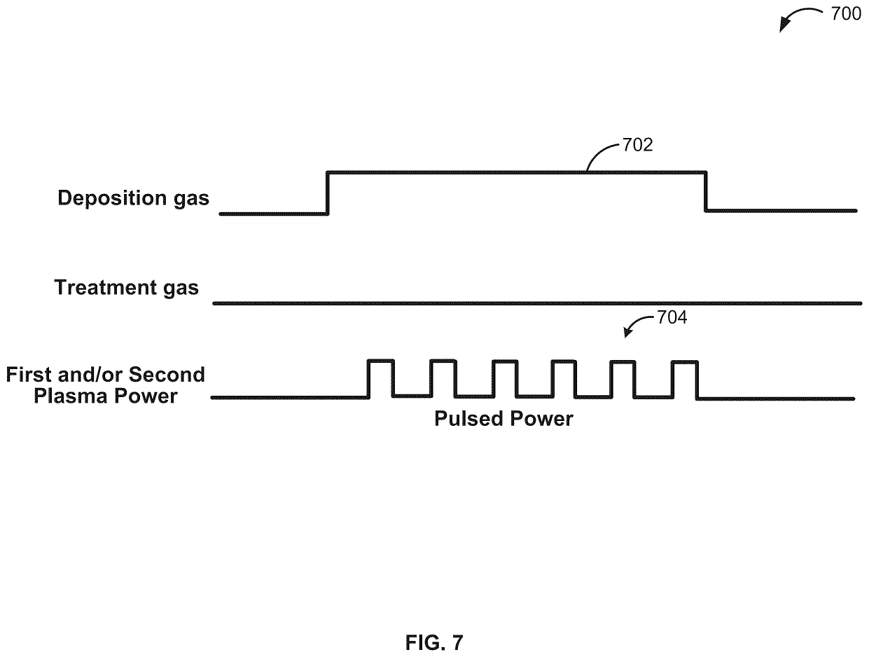

FIGS. 7-9 illustrate exemplary timing sequences 700, 800, and 900 for method 100. Timing sequences 700, 800, and 900 are meant to be illustrative and not limiting.

Sequence 700 illustrates a plasma-enhanced chemical vapor deposition process. As illustrated, a deposition gas can be flowed to a reaction chamber for a period 720. The deposition gas can include the silicon precursor, the first nitrogen-containing reactant, and optionally the second nitrogen-containing reactant and/or the hydrogen-containing reactant, such as those noted above in connection with steps 104-108. During period 704, pulsed first and/or second plasma power is provided to form a (e.g., continuous) plasma within a reaction chamber. The first and/or second power can be as described above in connection with steps 110 and 112. In the example illustrated in FIG. 7, no treatment is performed.

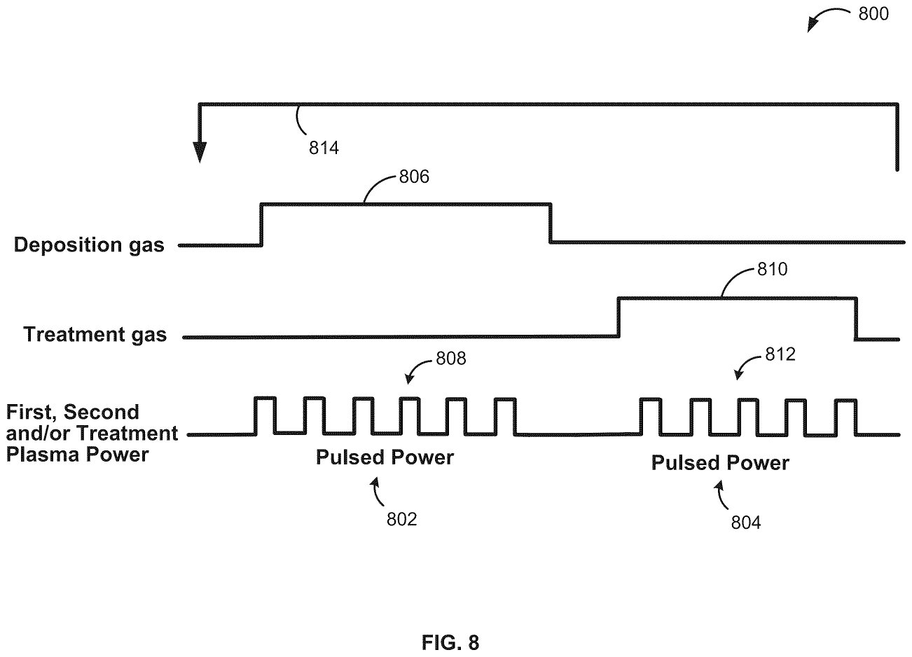

FIG. 8 illustrates another timing sequence 800 suitable for use with method 100. Sequence 800 is similar to sequence 700, except sequence 800 includes a deposition process 802, which can be the same or similar to deposition process 114, and a treatment step 804, which can be the same as treatment step 118. In the illustrated example, sequence 800 includes providing a deposition gas (e.g., the silicon precursor, the first nitrogen-containing reactant, and optionally the second nitrogen-containing reactant and/or the hydrogen-containing reactant) for a period 806 and providing pulsed first and/or second plasma power to form a (e.g., continuous) plasma within a reaction chamber during period 808. A treatment gas may not flow to the reaction chamber during deposition process 802. During treatment step 804, a treatment gas can be flowed to the reaction chamber or another reaction chamber during period 810 and pulsed treatment plasma power can be applied to form a (e.g., continuous) plasma within the reaction chamber during period 812. Sequence 800 can be repeated one or more times as illustrated by loop 814.

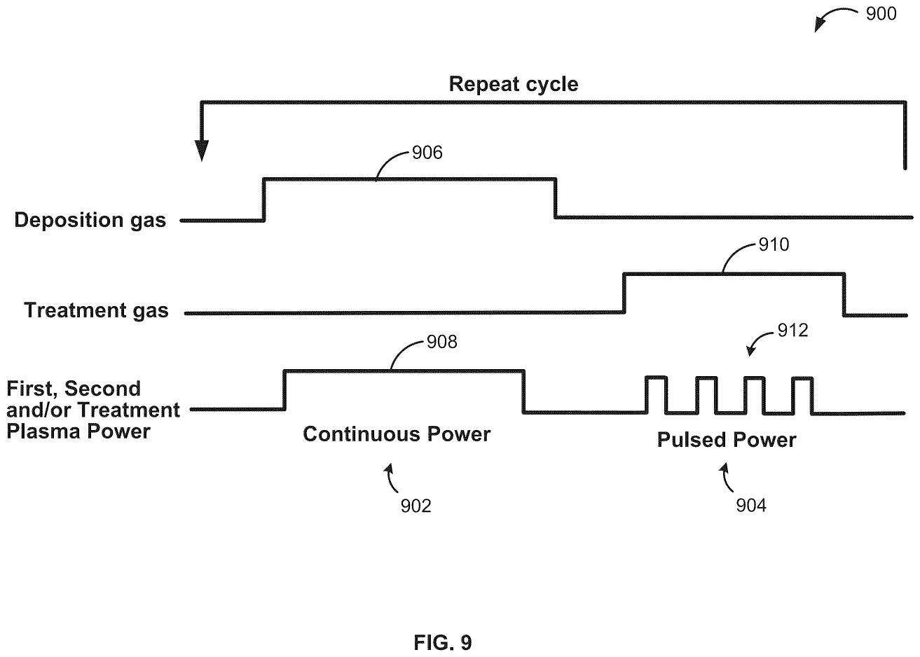

FIG. 9 illustrates another process sequence 900 suitable for use with method 100. Sequence 900 includes a deposition process 902, which can be the same or similar to deposition process 114, and a treatment step 904, which can be the same as treatment step 118. Sequence 900 can be the same as sequence 800, except deposition process 902 includes providing a deposition gas, which can be as described above, for a period 906 and providing a continuous plasma power (e.g., the first and/or second plasma power as described above) for a period 908. Treatment step 904 includes providing a treatment gas for a period 910 and applying a pulsed treatment plasma power for a period 912. Treatment step 904 can be the same as treatment step 804 or 118.

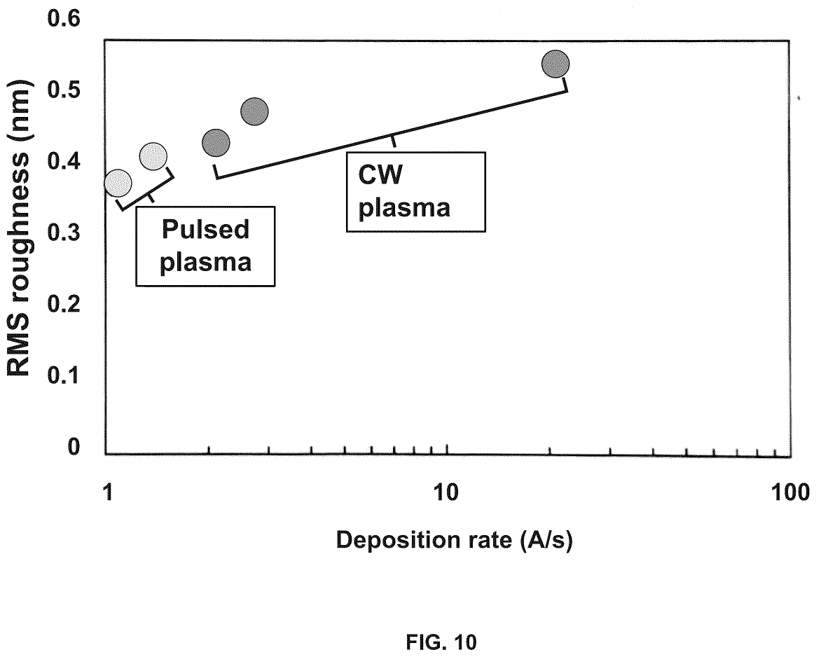

FIG. 10 illustrates surface roughness vs deposition rate for SiN films deposited using pulsed plasma deposition power (e.g., during step 110 and/or 112) and for a constant power during step 110 and 112. As shown, with the lower deposition rate, surface roughness decreases.

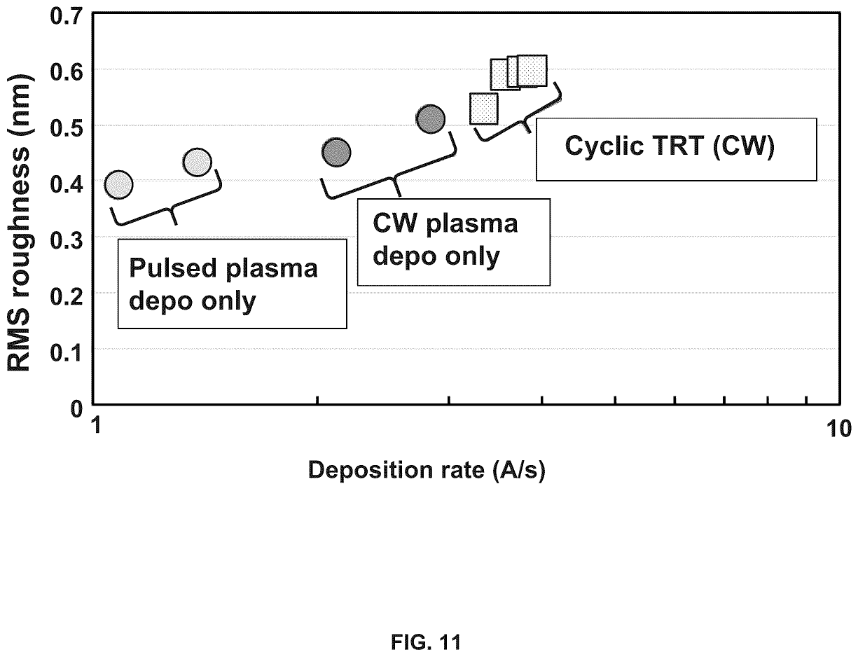

FIG. 11 illustrates effects of cyclic deposition and continuous wave (CW) plasma treatment on roughness. A cyclic deposition process with a continuous wave treatment step increases the deposition rate (thickness divided by total depo time for cyclic process) which increases the roughness. It is thought that the continuous wave plasma treatment generates byproduct deposition during the treatment process (so called redeposition). Even though plasma treatment can generally make a surface smooth by densification and etching of surface, redeposition generates a relatively rough surface again. Pulsed treatment plasma power can reduce the redeposition of byproducts during treatment. Pulsed plasma may have an off time of plasma or a weak plasma, and this off/weak time may help to evacuate the byproduct in the process area and suppress the redeposition.

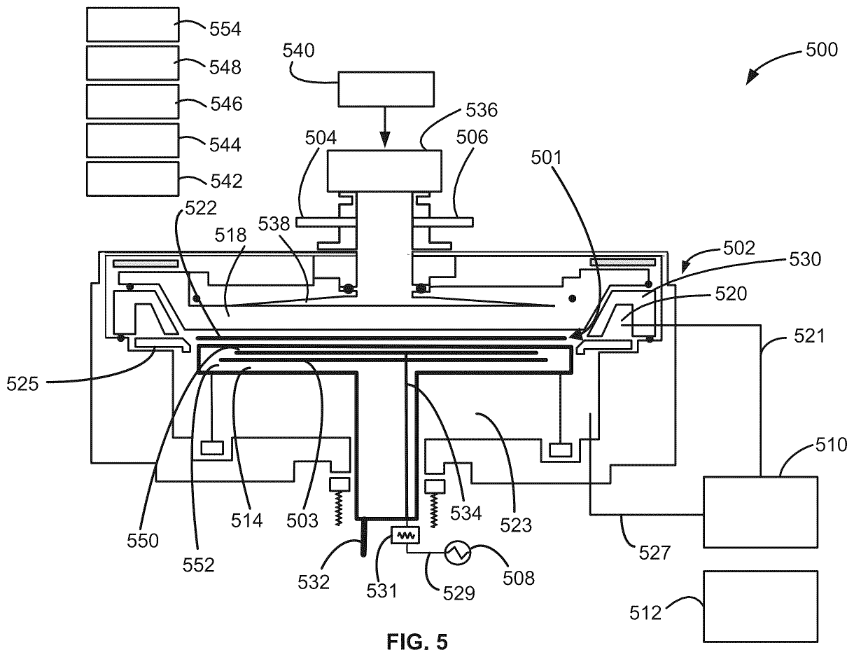

A reactor system 500 in accordance with exemplary embodiments of the disclosure is illustrated in FIG. 5. Reactor system 500 can be used to perform one or more steps or substeps as described herein and/or to form one or more structures or portions thereof as described herein.

Reactor system 500 includes a pair of electrically conductive flat-plate electrodes 514, 518 in parallel and facing each other in an interior 501 (reaction zone) of a reaction chamber 502. A plasma can be excited within reaction chamber 502 by applying, for example, plasma power from plasma power source(s) 508 to one electrode (e.g., electrode 514) and electrically grounding the other electrode (e.g., electrode 518). Power source(s) 508 can be coupled to electrode 514 via a transmission line 529, an (e.g., RF) filter 531, and a conductive rod 534. Power source(s) 508 can provide the first and second and treatment powers with frequencies and waves as described herein. Feeding power to lower electrode/susceptor 514 prevents or mitigates parasitic discharge at top electrode 518. The first plasma power frequencies as described herein are sensitive to the parasitic capacitance, so it is easy to discharge. Further, cleaning can use the relatively large upper volume 538 showerhead electrode 518 to deliver cleaning radical species formed from cleaning gas from a cleaning gas source 540 and RPU 536 to chamber 501. But volume 538 tends to have abnormal discharge with VHF. By bottom feeding of at least the first plasma power, the system becomes simple and enables one to have high density plasma generation in the process space only. The bottom feed configuration also enables two or four reaction chambers configuration in one system or module.

A temperature regulator 503 can be provided in a lower stage 514 (the lower electrode or susceptor), and a temperature of a substrate 522 placed thereon can be kept at a desired temperature, such as the temperatures noted above. Susceptor 514 can include a body 552 formed of, for example, a ceramic, such as aluminum nitride. In some cases, susceptor 514 can include a conductive member 550, such as, for example, a wire, rod, or plate embedded within or on body 552 to distribute power from power source(s) 508.

Electrode 518 can serve as a gas distribution device, such as a shower plate or showerhead. Precursor gases, reactant gases, and a carrier or inert gas, if any, or the like can be introduced into reaction chamber 502 using one or more gas lines (e.g., reactant gas line 504 and precursor gas line 506, respectively, coupled to a reactant source and a precursor source). For example, an inert gas and a reactant (e.g., as described above) can be introduced into reaction chamber 502 using line 504 and/or a precursor, and a carrier gas (e.g., an inert gas as described above) can be introduced into the reaction chamber 502 using line 506. Although illustrated with two inlet gas lines 504, 506, reactor system 500 can include any suitable number of gas lines. System 500 can also include a silicon precursor source 542, comprising a first vessel and a silicon precursor, coupled to the reaction chamber; a first nitrogen-containing source 544, comprising a second vessel and a first nitrogen-containing reactant; a second nitrogen-containing source 546, comprising a third vessel and a second nitrogen-containing reactant; a hydrogen-containing source 548, comprising a fourth vessel and a hydrogen-containing reactant; and a treatment gas source 554, comprising a fifth vessel and a treatment gas.

In reaction chamber 502, a circular duct 520 with an exhaust line 521 can be formed within a metallic duct plate 530, through which gas in the interior 501 of the reaction chamber 502 can be exhausted to an exhaust source 510. Additionally, a transfer chamber 523 can be provided with a seal gas line 532 to introduce seal gas into the interior 501 of reaction chamber 502 via the interior (transfer zone) of transfer chamber 523, wherein a separation plate 525 for separating the reaction zone 501 and the transfer chamber 523 can be provided (a gate valve through which a substrate is transferred into or from transfer chamber 523 is omitted from this figure). Transfer chamber 523 can also be provided with an exhaust line 527 coupled to exhaust source 510.

Reactor system 500 can include one or more controller(s) 512 programmed or otherwise configured to cause one or more method steps as described herein to be conducted. Controller(s) 512 are coupled with the various power sources, heating systems, pumps, robotics and gas flow controllers, or valves of the reactor, as will be appreciated by the skilled artisan. By way of example, controller 512 can be configured to control gas flow of a precursor, a reactant, and an inert gas into at least one of the one or more reaction chambers to form a layer on a surface of a substrate. Controller 512 can be further configured to provide power to form a plasma—e.g., within reaction chamber 502—as described herein. Controller 512 can be similarly configured to perform additional or alternative steps as described herein. By way of particular examples, controller 512 can be configured to provide the first nitrogen-containing reactant and the silicon precursor with a volumetric flow ratio of greater than 25:1, provide a first plasma power to an electrode within the reaction chamber while providing one or more of the silicon precursor and the first nitrogen-containing reactant, and provide a second plasma power to the electrode within the reaction chamber, wherein a frequency of the first plasma power is between about 50 MHz and about 200 MHz, and wherein a frequency of the second plasma power is between about 50 Hz and about 5 kHz. Controller 512 can additionally or alternatively be configured to provide a treatment plasma power to reaction chamber 502.

Controller 512 can include electronic circuitry and software to selectively operate valves, manifolds, heaters, pumps and other components included in system 500. Such circuitry and components operate to introduce precursors, reactants, and purge gases from the respective sources. Controller 512 can control timing of gas pulse sequences, temperature of the substrate and/or reaction chamber, pressure within the reaction chamber, and various other operations to provide proper operation of the system 500.

Controller 512 can include control software to electrically or pneumatically control valves to control flow of precursors, reactants, and/or purge gases into and out of the reaction chamber 502. Controller 512 can include modules, such as a software or hardware component, e.g., an FPGA or ASIC, which perform certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 500, substrates, such as semiconductor wafers, are transferred from, e.g., a substrate handling area 523 to the reaction zone 501. Once substrate(s) are transferred to reaction zone 501, one or more gases, such as precursors, reactants, carrier gases, and/or purge gases, are introduced into reaction chamber 502.

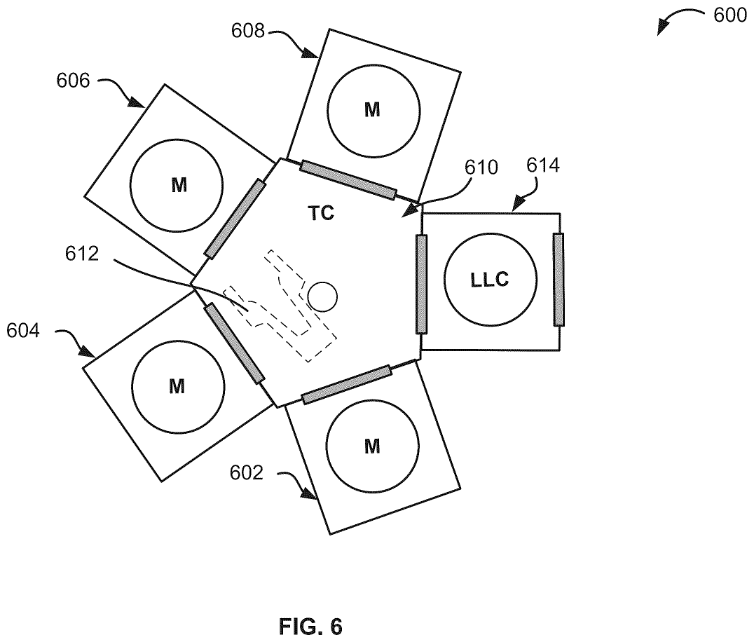

FIG. 6 illustrates a reactor system 600 that includes a plurality of modules 602-608, each of which can include one or more (e.g., 1, 2, or 4) reaction chambers, such as reaction chamber 502, described above. Modules 602-608 can be disposed around and/or coupled to a transfer chamber 610 that includes a transfer tool 612 for transferring substrates between modules 602-608 and a load lock chamber 614 and between modules 602-608 (e.g., through transfer chamber 610). For example, a substrate can be disposed in different chambers or modules for different steps of a method described herein. A module can include one or more controllers as described herein.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a structure comprising a silicon nitride layer, the method comprising:
providing a substrate within a reaction chamber of a reactor;
providing a silicon precursor within the reaction chamber;
providing a first nitrogen-containing reactant within the reaction chamber;
providing a first plasma power to an electrode within the reaction chamber while providing one or more of the silicon precursor and the first nitrogen-containing reactant; and
providing a second plasma power to the electrode within the reaction chamber while providing one or more of the silicon precursor and the first nitrogen-containing reactant,
wherein a frequency of the first plasma power is greater than a frequency of the second plasma power.

2. The method of claim 1, wherein the silicon precursor comprises a silane.

3. The method of claim 1, further comprising a treatment step.

4. The method of claim 3, wherein the treatment step comprises providing pulsed treatment plasma power to the electrode.

5. The method of claim 1, wherein the method further comprises a step of providing a second nitrogen-containing reactant.

6. The method of claim 1, wherein a ratio of a flowrate of the first nitrogen-containing reactant to a flowrate of the silicon precursor is greater than 25, greater than 50, or is between about 1500 and about 2000.

7. The method of claim 1, wherein the method further comprises a step of providing a hydrogen-containing reactant to the reaction chamber.

8. The method of claim 7, wherein a ratio of a flowrate of the hydrogen-containing reactant to a flowrate of the silicon precursor is greater than 5 or is between about 80 and about 800.

9. The method of claim 1, wherein the electrode is within a susceptor within the reaction chamber.

10. The method of claim 9, wherein the susceptor comprises a body comprising one or more of aluminum nitride or aluminum.

11. The method of claim 9, wherein the first plasma power and the second plasma power are provided via a conductive rod from a lower region of the reactor.

12. The method of claim 1, wherein a power of the first plasma power is between 10 W and 2000 W.

13. The method of claim 1, wherein a power of the second plasma power is between greater than 0 W and 1000 W.

14. The method of claim 1, wherein a power of the first plasma power is greater than a power of the second plasma power.

15. The method of claim 1, wherein a power of the first plasma power is at least 2 times or at least 10 times greater than a power of the second plasma power.

16. The method of claim 1, wherein a power of the second plasma power is pulsed at a pulsed frequency.

17. The method of claim 16, wherein the pulsed frequency is between about 50 Hz and about 5 kHz.

18. A method of forming a structure comprising a silicon nitride layer, the method comprising:
providing a substrate within a reaction chamber of a reactor;
providing a silicon precursor within the reaction chamber;
providing a first nitrogen-containing reactant within the reaction chamber; and
providing a first plasma power to an electrode within the reaction chamber while providing one or more of the silicon precursor and the first nitrogen-containing reactant,
wherein a frequency of the first plasma power is between about 50 MHz and about 200 MHz, and
wherein a ratio of a flowrate of the first nitrogen-containing reactant to a flowrate of the silicon precursor is greater than 25, greater than 50, or between about 1500 and about 2000.

19. The method of claim 18, further comprising:
providing a second plasma power to the electrode within the reaction chamber while providing one or more of the silicon precursor and the first nitrogen-containing reactant,
wherein a frequency of the first plasma power is greater than a frequency of the second plasma power.

20. The method of claim 18, wherein the method further comprises a step of providing a hydrogen-containing reactant to the reaction chamber.

21. The method of claim 20, wherein a ratio of a flowrate of the hydrogen-containing reactant to a flowrate of the silicon precursor is greater than 5 or is between about 80 and about 800.

22. The method of claim 18, further comprising a treatment step.

23. A reactor system comprising:
a reaction chamber;
a silicon precursor source, comprising a first vessel and a silicon precursor, coupled to the reaction chamber;
a first nitrogen-containing source, comprising a second vessel and a first nitrogen-containing reactant;
a second nitrogen-containing source, comprising a third vessel and a second nitrogen-containing reactant;
a hydrogen-containing source, comprising a fourth vessel and a hydrogen-containing reactant;
at least one plasma power source, and
a controller configured to:
provide the first nitrogen-containing reactant and the silicon precursor with a volumetric flow ratio of greater than 25:1;
provide a first plasma power to an electrode within the reaction chamber while providing one or more of the silicon precursor and the first nitrogen-containing reactant; and
provide a second plasma power to the electrode within the reaction chamber,
wherein a frequency of the first plasma power is between about 50 MHz and about 200 MHz, and
wherein a frequency of the second plasma power is between about 50 Hz and about 5 kHz.
